(19) United States
(12) Patent Application Publication
(10) Pub. No.: US 2026/0331052 A1
(43) Pub. Date: Oct. 22, 2026

(54) DISPLAY PANEL

(71) Applicant: LG Display Co., Ltd., Seoul (KR)

(72) Inventors: Jae Hyung JO, Paju-si (KR); Won Ho LEE, Paju-si (KR)

(73) Assignee: LG Display Co., Ltd., Seoul (KR)

(21) Appl. No.: 19/544,104

(22) Filed: Feb. 19, 2026

(30) Foreign Application Priority Data
Apr. 18, 2025 (KR) 10-2025-0050806

(51) Int. Cl. G09G 3/3233; G09G 3/3275; G09G 3/36; H10K 59/131

(52) U.S. Cl. CPC G09G 3/3233; G09G 3/3275; H10K 59/131; G09G 3/3688; G09G 2300/0426; G09G 2300/0842

(57) ABSTRACT

A display panel can include a plurality of pixels arranged in a first direction and a second direction that intersect each other, a plurality of signal output terminals configured to supply data signals, and a plurality of data lines connected to the plurality of signal output terminals and configured to transfer the data signals to the pixels. The plurality of pixels includes a first pixel connected to a first signal output terminal, a second pixel connected to a second signal output terminal, and third pixels arranged between the first pixel and the second pixel in the first direction and configured to be alternately connected to the first and second signal output terminals in the second direction.

### CROSS-REFERENCE TO RELATED APPLICATION

This application claims priority to and the benefit of Korean Patent Application No. 2025-0050806, filed in the Republic of Korea on Apr. 18, 2025, the disclosure of which is hereby expressly incorporated by reference in its entirety.

### BACKGROUND

### 1. Field

The present disclosure relates to a display panel, and more specifically, to a display panel capable of reducing the number of source driver integrated circuits (ICs) and a display device including the display panel.

### 2. Discussion of the Related Art

With the advancement of information technology, a market for display devices serving as a medium between a user and information has expanded. Accordingly, display devices such as organic light emitting displays (OLEDs), quantum dot displays (QDDs), liquid crystal displays (LCDs), and plasma display panels (PDPs) have been widely used.

For example, a liquid crystal display or an organic light emitting display includes a display panel including a plurality of sub-pixels, a driver configured to output driving signals for driving the display panel, a power supply configured to generate power to be supplied to the display panel or the driver, and the like. The driver includes a gate driver, a data driver, and the like.

### SUMMARY OF THE DISCLOSURE

One object of the present disclosure is to reduce the number of source driver integrated circuits (ICs) configured to convert data signals into voltage signals and apply the voltage signals to a data driver, e.g., for a display device.

Another object of the present disclosure is to minimize signal interference which can occur as the number of the source driver ICs is reduced.

The problems to be solved or addressed by aspects of the present disclosure are not limited to the above-mentioned problems or limitations associated with the related art, and other unmentioned problems and limitations will be clearly understood by those skilled in the art to which the technical ideas of the present disclosure belongs from the description below.

A display panel according to an embodiment of the present disclosure can include a plurality of pixels arranged in a first direction and a second direction that intersect each other; a plurality of signal output terminals configured to supply data signals; and a plurality of data lines connected to the signal output terminals and configured to transfer the data signals to the plurality of pixels, wherein the plurality of pixels can include a first pixel connected to a first signal output terminal, a second pixel connected to a second signal output terminal, and third pixels arranged between the first pixel and the second pixel in the first direction and configured to be alternately connected to the first signal output terminal and the second signal output terminal in the second direction.

A display panel according to an embodiment of the present disclosure can reduce the number of source driver ICs.

A display panel according to an embodiment of the present disclosure can minimize signal interference between electrodes.

The effects of the present disclosure are not limited to the above-mentioned effects, and other unmentioned effects will be clearly understood by those skilled in the art to which the technical idea of the present disclosure belongs from the description below.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a plan view of a display panel according to an embodiment of the present disclosure;

FIG. 2 is a circuit diagram of a sub-pixel circuit according to an embodiment of the present disclosure;

FIG. 3 is a schematic circuit diagram according to an embodiment of the present disclosure;

FIG. 4 is a schematic circuit diagram according to an embodiment of the present disclosure;

FIG. 5 is a schematic circuit diagram according to another embodiment of the present disclosure;

FIGS. 6A to 6D are modified examples of an area A of FIG. 5 according to aspects of the present disclosure;

FIG. 7 is a plan view illustrating a portion of the area A of FIG. 5 according to a first embodiment of the present disclosure;

FIG. 8 is a plan view illustrating an area B of FIG. 5 according to aspects of the present disclosure;

FIG. 9 is a cross-sectional view taken along line I-I′ of FIG. 7 according to aspects of the present disclosure;

FIG. 10 is a plan view illustrating a portion of the area A of FIG. 5 according to a second embodiment of the present disclosure;

FIG. 11 is a cross-sectional view taken along line II-II′ of FIG. 10 according to aspects of the present disclosure; and

FIG. 12 is a plan view illustrating an area D of FIG. 5 according to aspects of the present disclosure.

### DETAILED DESCRIPTION OF THE EMBODIMENTS

Advantages and features of the present disclosure, and methods for achieving them will become apparent with reference to embodiments described later in detail together with the accompanying drawings. However, the present disclosure is not limited to the embodiments disclosed below, but can be implemented in various different forms, and merely the present embodiments are provided to make the disclosure of the present specification complete, and to completely inform those of ordinary skill in the art to which the present disclosure pertains of the scope of the disclosure.

Shapes, sizes, ratios, angles, numbers, and the like disclosed in the drawings for describing embodiments of the present disclosure are examples, and thus the present disclosure is not limited to matters shown in the drawings. In addition, when describing the present disclosure, if it is determined that a detailed description of related known technologies can unnecessarily obscure the gist of the present disclosure, the detailed description thereof will be omitted.

When terms such as ‘comprises’, ‘has’, ‘consists of’, and the like are used in the present specification, other parts can be added unless ‘only’ is used. When a component is expressed in singular form, a case including plural is included unless there is a special explicit description.

In interpreting components, an error range is included even if there is no separate explicit description.

In the case of a description of a positional relationship, for example, when a positional relationship between two parts is described using terms such as ‘on’, ‘on an upper part’, ‘on a lower part’, ‘on a side’, and the like, one or more other parts can be positioned between the two parts unless ‘directly’or ‘immediately’ is used.

When an element or layer is referred to as being on another element or layer, it includes both a case where the element or layer is directly on the other element or a case where another layer or another element is interposed therebetween.

In addition, although term such as first, second, and the like are used to describe various components, these components are not limited by these terms. These terms are only used to distinguish one component from another component. Therefore, a first component mentioned below can be a second component within the technical spirit of the present disclosure.

Throughout the specification, the same reference numerals refer to the same components.

Sizes and thicknesses of respective components shown in the drawings are illustrated for convenience of description, and the present disclosure is not necessarily limited to the sizes and thicknesses of the components shown in the drawings.

Features of various embodiments of the present disclosure can be partially or entirely combined or associated with each other, and can be technically variously interlocked and driven, and each of the embodiments can be implemented independently of each other or can be implemented together in an associated relationship.

In the present disclosure, ‘device’ can include a display device such as a liquid crystal module (LCM) including a display panel and a driver for driving the display panel, and an organic light emitting display module (OLED Module). In addition, the device can include a set electronic apparatus or a set device such as an equipment apparatus including a notebook computer, a television, a computer monitor, an automotive apparatus or other forms of a vehicle, which are complete products or final products including the LCM, the OLED module, and the like, and a mobile electronic apparatus such as a smartphone or an electronic pad.

Therefore, the display device in the present disclosure can include the display device itself such as the LCM, the OLED module, and the like, and the set device which is an application product or a device for final consumers including the LCM, the OLED module, and the like.

In some embodiments, the LCM and the OLED module composed of a display panel and a driver can be expressed as a ‘display device’, and an electronic device as a complete product including the LCM and the OLED module can be distinguished and expressed as a ‘set device’. For example, the display device can include a display panel of liquid crystal (LCD) or organic light emitting (OLED) (or the like), and a source PCB which is a controller for driving the display panel. The set device can further include a set PCB which is a set controller electrically connected to the source PCB and driving the entire set device. The display device can further include other components known in the art in addition to the display panel.

A display panel used in embodiments of the present disclosure can include all types of display panels such as a liquid crystal display panel, an organic light emitting diode (OLED) display panel, and an electroluminescent display panel. However, the display panel is not limited thereto. Further, a display device/apparatus according to aspects of the present disclosure can include a display panel having a plurality of pixels having sub-pixels, a driver configured to output driving signals for driving the display panel, a power supply configured to generate power to be supplied to the display panel or the driver, and the like. The driver can include a gate driver, a data driver, and the like.

Features of various embodiments of the present disclosure can be partially or entirely combined or associated with each other, and can be technically variously interlocked and driven, and each of the embodiments can be implemented independently of each other or can be implemented together in an associated relationship. Further, the term “can” fully encompasses all the meanings and coverages of the term “may” and vice versa.

Hereinafter, various embodiments of the present invention will be described in detail with reference to the accompanying drawings. All the components of each display panel, each display device, and each display apparatus according to all embodiments of the present disclosure are operatively coupled and configured. Scales of components shown in the drawings have scales different from actual scales for convenience of description, and thus are not limited to the scales shown in the drawings.

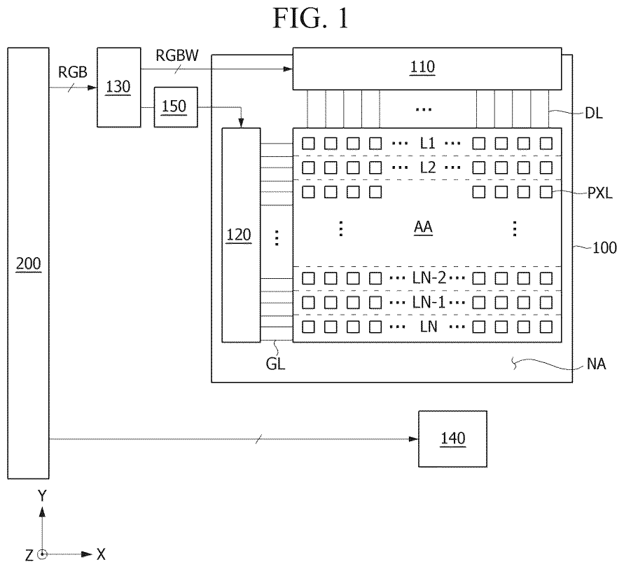

FIG. 1 is a schematic plan view of a display panel of a display device according to an embodiment of the present disclosure.

Referring to FIG. 1, each of a horizontal direction (X) and a vertical direction (Y) of a display panel 100 can be a length direction and a width direction of the display panel 100. In addition, each of the horizontal direction (X) and the vertical direction (Y) of the display panel 100 can also be expressed as a row direction and a length direction. A thickness direction (Z) can mean a direction perpendicular to a plane having the horizontal direction (X) and the vertical direction (Y) of the display panel 100. In addition, the display panel 100 can have a cross-section in the thickness direction (Z).

The display panel 100 according to an embodiment of the present invention can include a display panel driving circuit for writing pixel data to pixels, and a power supply unit 140 generating power required for driving the pixels and the display panel driving circuit.

A display area AA (or active area) of the display panel 100 can include a pixel array for displaying an input image. The pixel array can include a plurality of data lines DL, a plurality of gate lines GL crossing the data lines DL, and pixels arranged in a matrix form. The display panel 100 can include power lines commonly connected to the pixels. The power lines can be connected to constant voltage nodes of pixel circuits to supply a constant voltage required for driving pixels (PXL) to the pixels (PXL). The power lines can be implemented as stripe or mesh wirings and commonly connected to the pixels of the display panel 100.

Each of the pixels PXL can include a plurality of sub-pixels for color implementation. Each of the pixels PXL can include three, four, or more sub-pixels. The plurality of sub-pixels can be arranged in various manners.

For example, when each of the pixels PXL includes first to third sub-pixels having different colors, each of the sub-pixels can emit blue, red, and green light, but is not limited thereto. For example, when each of the pixels PXL includes the first to fourth sub-pixels, the first to fourth sub-pixels can further include a white sub-pixel in addition to the above-described three sub-pixels, but is not limited thereto.

Each of the sub-pixels can include pixel circuits configured to drive a light-emitting element. Each of the pixel circuits can be connected to a data line DL, a gate line GL, and a power supply line. Each of the sub-pixels can be divided into a circuit part and a light-emitting part.

The pixel array can include a plurality of pixel lines L1 to LN, where N can be a real number such as a positive integer. Each of the pixel lines L1 to LN can include pixels of one line disposed along an X-axis direction X in the pixel array of the display panel 100. One horizontal period is a time obtained by dividing one frame period by the total number of the pixel lines L1 to LN.

The power supply unit 140 outputs a voltage required for driving the pixels of the display panel 100 and the display panel driving circuit by using a DC-DC (direct current-direct current) converter. The DC-DC converter can include a charge pump, a regulator, a buck converter, a boost converter, and the like.

The display panel driving circuit writes pixel data of an input image to pixels of the display panel 100 under control of a timing controller 130. The display panel driving circuit can include a data driver 110 and a gate driver 120.

The display panel driving circuit can drive the pixels using a 2.5 RD (rate driving) structure. The display panel driven by the 2.5 RD structure can be connected to 2.5 pixels per one channel (or one signal output terminal), thereby reducing the number of channels of the data driver 110 and the number of source driver integrated circuits (ICs). The reduction in the number of channels and source driver ICs can lead to a decrease in manufacturing costs.

The display panel driving circuit can further include a touch sensor driver configured to drive touch sensors. Although the touch sensor driver is omitted from FIG. 1, it can be integrated into a single source driver IC along with the data driver 110.

The data driver 110 can receive pixel data of an input image, which are received as a digital signal from a timing controller 130, and output data voltages. The data voltages can be output via output buffers in respective channels of the data driver 110.

The gate driver 120 can be disposed in a non-display area NA, can be disposed at least partially within a display area AA in which an input image is reproduced, or can be formed on the display panel 100 together with a thin-film transistor (TFT) array and wires of the pixel array.

The gate driver 120 can be disposed on both sides or on one side of the non-display area NA of the display panel 100 with the display area AA interposed therebetween, and can supply gate pulses using a double-feeding scheme or a single-feeding scheme.

The gate driver 120 sequentially outputs pulses of a gate signal (hereinafter, referred to as ‘gate pulses’) to the gate lines under control of the timing controller 130. The gate driver 120 can sequentially supply the signals to the gate lines GL by shifting the gate pulses using a shift register. The gate driver 120 can include one or more shift registers outputting pulses of gate signals.

The timing controller 130 can receive digital video data of an input image and timing signals synchronized with the data from a host system 200. The timing controller 130 generates a data timing control signal for controlling the operation timing of the data driver 110 and a gate timing control signal for controlling the operation timing of the gate driver 120, based on the timing signals received from the host system 200.

For example, the timing controller 130 can add white data to three primary color pixel data RGB inputted from the host system, convert the data into four-color sub-color data RGBW, and transfer them to the data driver 110. A known color conversion algorithm can be used as a method for converting the three primary color pixel data RGB into the four-color sub-color data RGBW including the white color data.

A level shifter 150 can receive the gate timing control signal from the timing controller 130, generate a start pulse and a shift clock, and provide them to the gate driver 120. The start pulse and the shift clock output from the level shifter 150 swing between a gate high voltage and a gate low voltage.

The host system 200 can include a main board. The host system can scale an image signal from a video source to match the resolution of the display panel 100 and transfer it together with the timing signals to the timing controller 130. The elements such as the timing controller 130, the level shifter 150, the power supply unit 140, the host system 200, etc. can be part of the display device including the display panel 100.

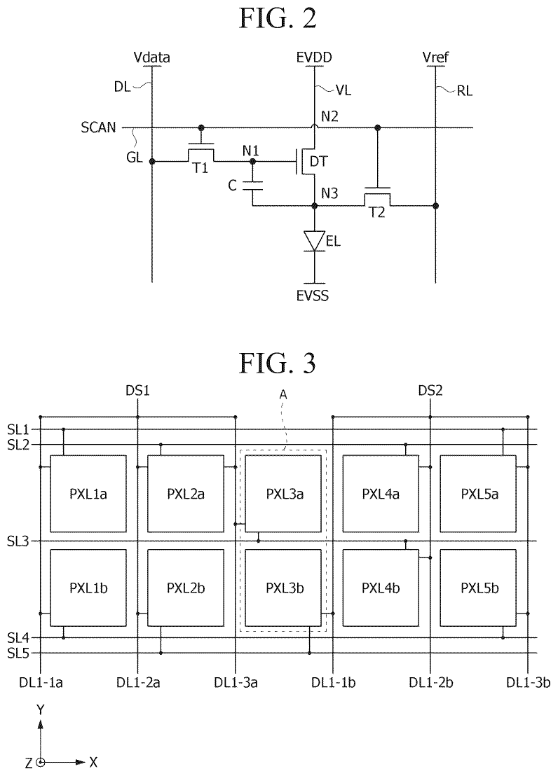

FIG. 2 is a circuit diagram of a sub-pixel circuit according to an embodiment of the present disclosure. The sub-pixel circuit for each of the sub-pixels of the display panel (e.g., 100 in FIG. 1) can have the configuration shown in FIG. 2.

Referring to FIG. 2, a circuit for each sub-pixel PXL (hereinafter, sub-pixel circuit) can be connected to a data line DL to which a data voltage Vdata of pixel data is applied, a gate line GL to which a gate pulse SCAN is applied, a driving voltage line VDDL to which a pixel driving voltage EVDD is applied, a low-potential voltage line VSSL to which a low-potential voltage EVSS is applied, and a reference voltage line RL to which a reference voltage Vref is applied.

Each sub-pixel circuit can include a light-emitting element EL, a plurality of transistors DT, T1, and T2, and a capacitor C. However, the structure of the sub-pixel circuit in the display panel of the present disclosure is not limited thereto.

The light-emitting element EL can be an organic light emitting diode (OLED) or an inorganic light-emitting element, such as a micro-LED. The light-emitting element EL can include, but is not limited to, a red light-emitting element, a green light-emitting element, and a blue light-emitting element. The anode electrode of the light-emitting element EL can be electrically connected to a driving element DT and can be disposed within a corresponding light-emitting area in each pixel. The light-emitting element EL is driven to emit light when a current is generated from the driving element DT, and the light is emitted to the outside of the display panel via the light-emitting area.

The driving element DT can generate a current according to the gate-source voltage, thereby driving the light-emitting element EL. The driving element DT includes a gate electrode connected to a first node N1, a first electrode connected to a second node N2, and a second electrode connected to a third node N3. A capacitor C is connected between the first node N1 and the third node N3. The second node N2 is connected to a driving voltage line VDDL. The third node N3 is connected to the anode electrode of the light-emitting element EL. The cathode electrode of the light-emitting element EL is connected to the low-potential voltage line VSSL to which the low-potential voltage EVSS is applied.

A first switching element T1 is connected between the data line DL and the first node N1. The first switching element T1 is turned on in response to the gate pulse SCAN. When the first switching element T1 is turned on, the data voltage Vdata of the pixel data is applied to the first node N1, thereby writing the pixel data to the sub-pixel. The first switching element T1 can include a gate electrode connected to the gate line GL, a first electrode connected to the data line DL, and a second electrode connected to the first node N1.

A second switching element T2 is connected between the third node N3 and the reference voltage line RL. The second switching element T2 is turned ON in response to the gate pulse SCAN. When the second switching element T2 is turned ON, the third node N3 is connected to the reference voltage line RL. The second switching element T2 can include a gate electrode connected to the gate line GL, a first electrode connected to the third node N3, and a second electrode connected to the reference voltage line RL.

Although the driving element DT is required to have uniform electrical characteristics in all sub-pixels, there can be differences between sub-pixels due to process variations and device characteristic deviations, and the difference can increase with the lapse of the driving time of the sub-pixels. In order to compensate for the electrical characteristic deviation of such a driving element DT, an external compensation circuit can be applied to the display panel driving circuit.

In the following embodiments, a gate line GL, a driving voltage line VL, a reference voltage line RL, a driving element DT, and first and second switching elements T1 and T2 can be referred to as follows. The gate line GL can be referred to as a scan line SL. The driving voltage line VL can be referred to as a driving voltage line VL1-1. The reference voltage line RL can be referred to as a reference voltage line VL2. The driving element DT can be referred to as a third transistor T3. The first switching element T1 and the second switching element T2 can be referred to as a first transistor T1 and a second transistor T2, respectively.

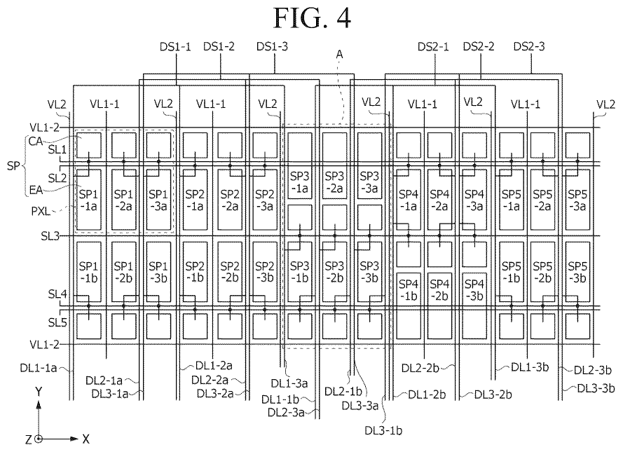

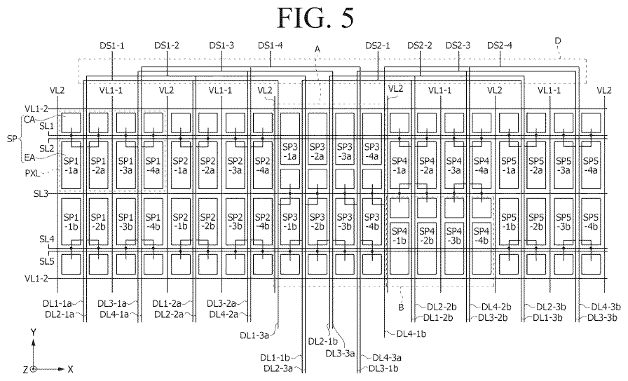

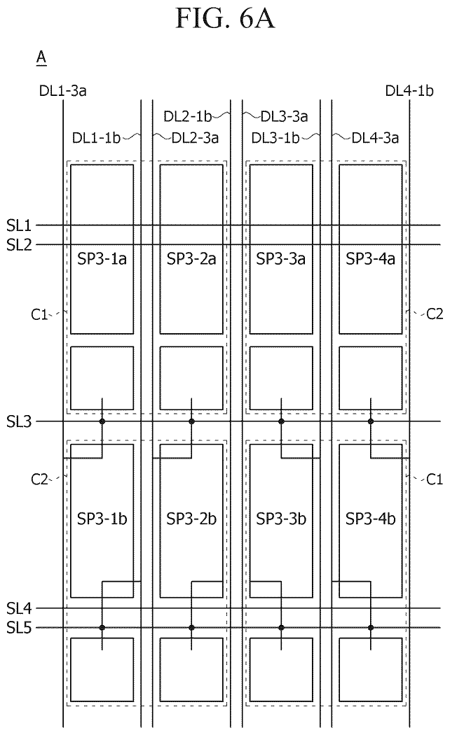

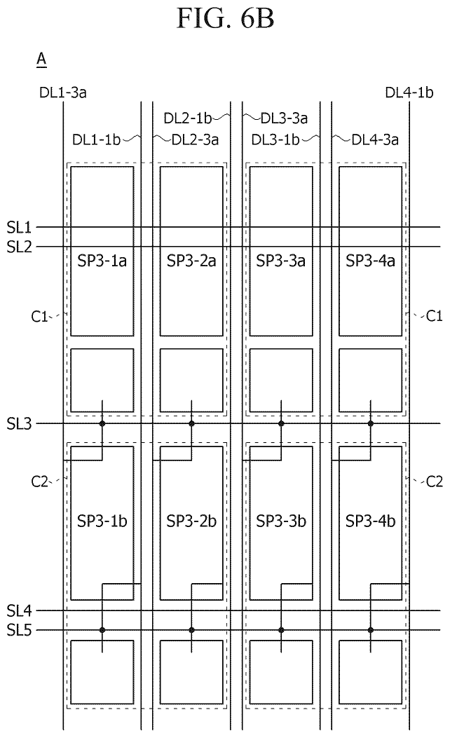

FIG. 4 is a schematic circuit diagram for three sub-pixels according to an embodiment of the present disclosure. FIG. 5 is a schematic circuit diagram for four sub-pixels according to an embodiment of the present disclosure. In the present disclosure, the display panel configured with three sub-pixels and four sub-pixels (e.g., FIGS. 4 and 5) is illustrated as an embodiment of the present disclosure in FIG. 3, but the number of sub-pixels is not limited thereto. FIGS. 6A to 6D are modified examples of an area A of FIG. 5.

The same reference numerals in FIG. 4 and FIG. 5 may not necessarily refer to the same color or signal. For example, the same reference numerals in FIG. 4 and FIG. 5 can indicate sub-pixels for emitting different colors or signal output terminals containing different color information. For example, a first-1a sub-pixel SP1-1a shown in FIG. 4 and a first-1a sub-pixel SP1-1a shown in FIG. 5 can emit different colors.

Referring to FIGS. 3 to 5, a display panel or a display device including the display panel according to an embodiment of the present disclosure includes a plurality of pixels PXL arranged in a first direction X and a second direction Y that intersect each other; a plurality of signal output terminals DS (including DS1 and DS2) configured to supply data signals; and a plurality of data lines DL connected to the plurality of signal output terminals DS and configured to transfer the data signals to the plurality of pixels PXL, wherein the plurality of pixels PXL can include a first pixel connected to a first signal output terminal DS1, a second pixel connected to a second signal output terminal DS2, and third pixels arranged between the first pixel and the second pixel in the first direction X and configured to be alternately connected to the first signal output terminal DS1 and the second signal output terminal DS2 in the second direction Y.

The plurality of pixels PXL can be formed at the intersections of the scan lines and the data lines. The plurality of pixels PXL can be arranged in a plurality of rows and a plurality of columns. For example, the plurality of pixels PXL can be arranged in a grid form.

The plurality of pixels PXL can include a first-a pixel PXL1a, a second-a pixel PXL2a, a third-a pixel PXL3a, a fourth-a pixel PXL4a, a fifth-a pixel PXL5a, a first-b pixel PXL1b, a second-b pixel PXL2b, a third-b pixel PXL3b, a fourth-b pixel PXL4b, and a fifth-b pixel PXL5b. According to an embodiment of the present disclosure, the first-a to fifth-a pixels PXL1a, PXL2a, PXL3a, PXL4a, and PXL5a and the first-b to fifth-b pixels PXL1b, PXL2b, PXL3b, PXL4b, and PXL5b can be repeatedly arranged as pixel units in a display area.

The first-a to fifth-a pixels PXL1a, PXL2a, PXL3a, PXL4a, and PXL5a and the first-b to fifth-b pixels PXL1b, PXL2b, PXL3b, PXL4b, and PXL5b can be arranged in a plurality of rows and a plurality of columns. For example, the first-a to fifth-a pixels PXL1a, PXL2a, PXL3a, PXL4a, and PXL5a can be sequentially arranged in a first row and first to fifth columns. For example, the first-b to fifth-b pixels PXL1b, PXL2b, PXL3b, PXL4b, and PXL5b can be sequentially arranged in a second row and the first to fifth columns.

Each of the plurality of pixels PXL can include a plurality of sub-pixels. Referring to FIG. 4, the display panel according to an embodiment can include three sub-pixels in each of the plurality of pixels PXL. The three sub-pixels can each be any one of red, green, and blue, but are not limited thereto.

Referring to FIGS. 3 and 4, the first-a pixel PXL1a can include a first-1a sub-pixel SP1-1a, a first-2a sub-pixel SP1-2a, and a first-3a sub-pixel SP1-3a. The second-a pixel PXL2a can include a second-1a sub-pixel SP2-1a, a second-2a sub-pixel SP2-2a, and a second-3a sub-pixel SP2-3a.

The third-a pixel PXL3a can include a third-1a sub-pixel SP3-1a, a third-2a sub-pixel SP3-2a, and a third-3a sub-pixel SP3-3a. The fourth-a pixel PXL4a can include a fourth-1a sub-pixel SP4-1a, a fourth-2a sub-pixel SP4-2a, and a fourth-3a sub-pixel SP4-3a. The fifth-a pixel PXL5a can include a fifth-1a sub-pixel SP5-1a, a fifth-2a sub-pixel SP5-2a, and a fifth-3a sub-pixel SP5-3a.

The first-b pixel PXL1b can include a first-1b sub-pixel SP1-1b, a first-2b sub-pixel SP1-2b, and a first-3b sub-pixel SP1-3b. The second-b pixel PXL2b can include a second-1b sub-pixel SP2-1b, a second-2b sub-pixel SP2-2b, and a second-3b sub-pixel SP2-3b. The third-b pixel PXL3b can include a third-1b sub-pixel SP3-1b, a third-2b sub-pixel SP3-2b, and a third-3b sub-pixel SP3-3b.

The fourth-b pixel PXL4b can include a fourth-1b sub-pixel SP4-1b, a fourth-2b sub-pixel SP4-2b, and a fourth-3b sub-pixel SP4-3b. The fifth-b pixel PXL5b can include a fifth-1b sub-pixel SP5-1b, a fifth-2b sub-pixel SP5-2b, and a fifth-3b sub-pixel SP5-3b.

Referring to FIG. 5, the display panel according to another embodiment can include four sub-pixels SP in each of the plurality of pixels PXL. The four sub-pixels can each be any one of white, red, green, and blue, but are not limited thereto.

Referring to FIGS. 3 and 5, the first-a pixel PXL1a can include a first-1a sub-pixel SP1-1a, a first-2a sub-pixel SP1-2a, a first-3a sub-pixel SP1-3a, and a first-4a sub-pixel SP1-4a. The second-a pixel PXL2a can include a second-1a sub-pixel SP2-1a, a second-2a sub-pixel SP2-2a, a second-3a sub-pixel SP2-3a, and a second-4a sub-pixel SP2-4a. The third-a pixel PXL3a can include a third-1a sub-pixel SP3-1a, a third-2a sub-pixel SP3-2a, a third-3a sub-pixel SP3-3a, and a third-4a sub-pixel SP3-4a.

The fourth-a pixel PXL4a can include a fourth-1a sub-pixel SP4-1a, a fourth-2a sub-pixel SP4-2a, a fourth-3a sub-pixel SP4-3a, and a fourth-4a sub-pixel SP4-4a. The fifth-a pixel PXL5a can include a fifth-1a sub-pixel SP5-1a, a fifth-2a sub-pixel SP5-2a, a fifth-3a sub-pixel SP5-3a, and a fifth-4a sub-pixel SP5-4a.

The first-b pixel PXL1b can include a first-1b sub-pixel SP1-1b, a first-2b sub-pixel SP1-2b, a first-3b sub-pixel SP1-3b, and a first-4b sub-pixel SP1-4b. The second-b pixel PXL2b can include a second-1b sub-pixel SP2-1b, a second-2b sub-pixel SP2-2b, a second-3b sub-pixel SP2-3b, and a second-4b sub-pixel SP2-4b. The third-b pixel PXL3b can include a third-1b sub-pixel SP3-1b, a third-2b sub-pixel SP3-2b, a third-3b sub-pixel SP3-3b, and a third-4b sub-pixel SP3-4b.

The fourth-b pixel PXL4b can include a fourth-1b sub-pixel SP4-1b, a fourth-2b sub-pixel SP4-2b, a fourth-3b sub-pixel SP4-3b, and a fourth-4b sub-pixel SP4-4b. The fifth-b pixel PXL5b can include a fifth-1b sub-pixel SP5-1b, a fifth-2b sub-pixel SP5-2b, a fifth-3b sub-pixel SP5-3b, and a fifth-4b sub-pixel SP5-4b.

Each sub-pixel SP can include a light-emitting part EA and a circuit part CA. The circuit part CA includes a pixel circuit configured to drive each sub-pixel SP and can include at least one transistor. The light-emitting part EA can be an area in which light from a light-emitting element electrically connected to the pixel circuit is emitted.

The light-emitting part EA and the circuit part CA can be disposed side by side in a column direction Y. The sub-pixels SP included in one pixel PXL can have the same arrangement direction of the respective light-emitting parts EA and circuit parts CA, but the present disclosure is not limited thereto.

The arrangement of the light-emitting part EA and the circuit part CA can vary depending on the number and arrangement of scan lines to which the plurality of pixels PXL are connected. According to an embodiment of the present disclosure, in the 2.5 RD structure, at least five scan lines, to which scan signals are supplied, can be provided per pixel unit of two rows and five columns. However, in the present disclosure, the number of scan lines, the arrangement structure of the plurality of scan lines, and the pixels connected to the scan lines are not limited to those disclosed.

According to an embodiment of the present disclosure, a first scan line SL1, a second scan line SL2, a third scan line SL3, a fourth scan line SL4, and a fifth scan line SL5, which are supplied per pixel unit, can be included. The five scan lines can be disposed to minimize a decrease in the aperture ratio of each sub-pixel SP.

Each of the first to fifth scan lines SL1, SL2, SL3, SL4, and SL5 can be disposed in a row direction and can be spaced apart from each other in a column direction. The first and second scan lines SL1 and SL2 can be disposed to supply signals to the sub-pixels SP arranged in a first row. The fourth and fifth scan lines SL4 and SL5 can be disposed to supply signals to the sub-pixels SP arranged in a second row. The third scan line SL3 can be disposed between the pixels arranged in the first row and the pixels arranged in the second row to supply signals to at least one of the plurality of pixels arranged in each of the first row and the second row.

The pixels arranged in the first row and pixels arranged in the second row can have an overall flipped structure with respect to the third scan line SL3, excluding some pixels. The flipped structure can mean that the arrangements of the circuit part CA and the light-emitting part EA of the pixels arranged in the first row and the pixels arranged in the second row are inverted with respect to each other. Here, some pixels that are not flipped with respect to the third scan line SL3 can be pixels connected to the third scan line SL3. In this case, pixels arranged in the second direction Y, including some pixels connected to the third scan line SL3, may not have the flipped structure with respect to the third scan line SL3.

The first-a to fifth-a pixels PXL1a, PXL2a, PXL3a, PXL4a, and PXL5a can have their circuit parts CA and light-emitting parts EA disposed in the same direction, excluding the pixels connected to the third scan line SL3. For example, each of the first-a, second-a, fourth-a, and fifth-a pixels PXL1a, PXL2a, PXL4a, and PXL5a can be arranged such that the light-emitting part EA is closer to the second row than the circuit part CA, while the third-a pixel PXL3a can be arranged such that the circuit part CA is closer to the second row than the light-emitting part EA.

The first and second scan lines SL1 and SL2 can be disposed between the circuit part CA and the light-emitting part EA of each of at least four pixels among the five first-a to fifth-a pixels PXL1a, PXL2a, PXL3a, PXL4a, and PXL5a arranged in the first row. The first and second scan lines SL1 and SL2 can be disposed to cross the light-emitting part EA of at least one pixel arranged in the first row. For example, when the third-a pixel PXL3a is connected to the third scan line SL3, the first and second scan lines SL1 and SL2 can be disposed to cross the light-emitting part EA of the third-a pixel PXL3a.

Each of the first and second scan lines SL1 and SL2 can be connected to two pixels among the four pixels arranged in the first row. For example, the first scan line SL1 can be connected to the first-a and fifth-a pixels PXL1a and PXL5a, and the second scan line SL2 can be connected to the second-a and fourth-a pixels PXL2a and PXL4a.

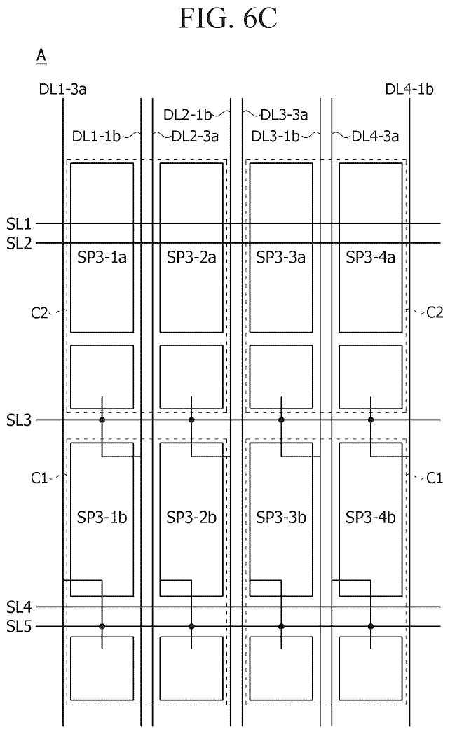

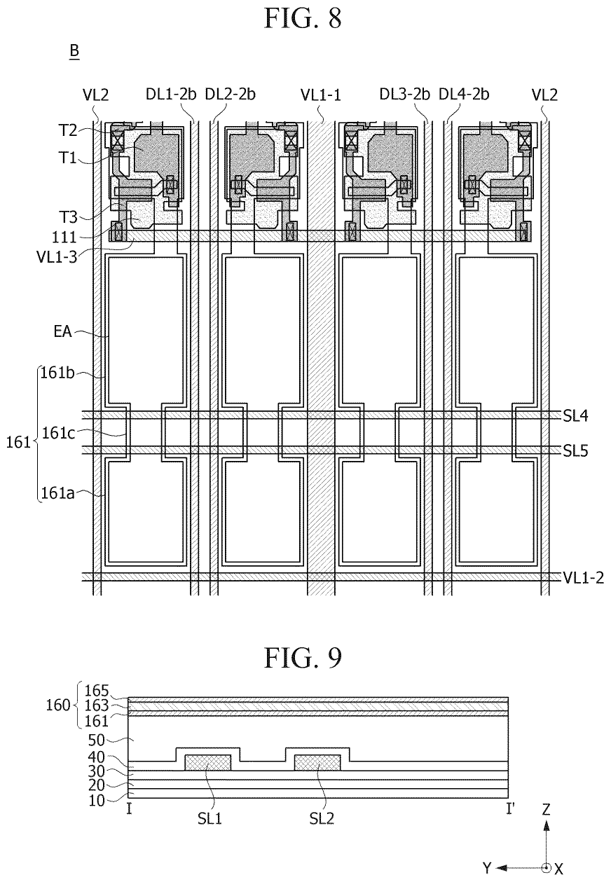

Connecting a scan line and a pixel (or a sub-pixel) can include the meaning of transferring a signal from the scan line to the pixel. Furthermore, connecting a scan line and a pixel (or a sub-pixel) can include the meaning that a transistor is formed at an intersection of the scan line and a data line connected to the pixel, so that when a signal is supplied to the scan line, the transistor is switched and a signal from the data line is supplied to the corresponding pixel. The transistor formed at the intersection of the scan line and the data line connected to the pixel can be disposed in a switching unit ND shown in FIGS. 7 and 10.

The sub-pixels disclosed in FIG. 4 and the sub-pixels disclosed in FIG. 5 can be connected to the first and second scan lines SL1 and SL2 in the same manner as the corresponding pixels. In addition, the connection relationships between the third to fifth scan lines SL3, SL4, and SL5 and the pixels described below can involve the pixels corresponding to the sub-pixels disclosed in FIGS. 4 and 5.

The first-b to fifth-b pixels PXL1b, PXL2b, PXL3b, PXL4b, and PXL5b can have their circuit parts CA and light-emitting parts EA disposed in the same direction, excluding the pixels connected to the third scan line SL3. For example, the first-b to third-b, and fifth-b pixels PXL1b, PXL2b, PXL3b, and PXL5b can be arranged such that the light-emitting part EA is closer to the first row than the circuit part CA, while the fourth-b pixel PXL4b can be arranged such that the circuit part CA is closer to the first row than the light-emitting part EA.

The fourth and fifth scan lines SL4 and SL5 can be disposed between the circuit part CA and the light-emitting part EA of each of at least four pixels among the five first-b to fifth-b pixels PXL1b, PXL2b, PXL3b, PXL4b, and PXL5b arranged in the second row. In addition, the fourth and fifth scan lines SL4 and SL5 can be disposed to cross the light-emitting part EA of at least one pixel arranged in the second row. For example, when the fourth-b pixel PXL4b is connected to the third scan line SL3, the fourth and fifth scan lines SL4 and SL5 can be disposed to cross the light-emitting part EA of the fourth-b pixel PXL4b.

Accordingly, each of the fourth and fifth scan lines SL4 and SL5 can be connected to two pixels among the five pixels of the pixel unit arranged in the second row. For example, the fourth scan line SL4 can be connected to the first-b and fifth-b pixels PXL1b and PXL5b, and the fifth scan line SL5 can be connected to the second-b and third-b pixels PXL2b and PXL3b.

The third scan line SL3 can be disposed between the pixels PXL1a, PXL2a, PXL3a, PXL4a, and PXL5a arranged in the first row and the pixels PXL1b, PXL2b, PXL3b, PXL4b, and PXL5b arranged in the second row.

In the pixels connected to the third scan line SL3, the circuit part CA can be disposed closer to the third scan line SL3 than the light-emitting part EA. The pixels connected to the third scan line SL3 can be disposed in an inverted form compared to pixels arranged in the same row. For example, at least one pixel among the pixels arranged in the same row can have the circuit part CA and the light-emitting part EA disposed in a direction opposite to that of the remaining pixels.

For example, the pixels connected to the third scan line SL3 can have the circuit part CA and the light-emitting part EA disposed in an inverted form compared to the pixels arranged in the same row. For example, the third scan line SL3 can be connected to the third-a and fourth-b pixels PXL3a and PXL4b. However, according to an embodiment of the present disclosure, the pixels connected to the third scan line SL3 in each row are not limited thereto.

A plurality of signal output terminals can output data voltages from the data driver (110 in FIG. 1). The plurality of signal output terminals can supply data signals to the plurality of pixels PXL via a plurality of data lines respectively connected thereto. Data lines receiving the same data signal from one signal output terminal can be connected to different scan lines to independently drive each pixel or each sub-pixel.

The plurality of signal output terminals can include a first signal output terminal DS1 and a second signal output terminal DS2. The first and second signal output terminals DS1 and DS2 can contain information of the same color.

The plurality of data lines can be connected to each of the plurality of signal output terminals. According to an embodiment, three data lines can be connected to each of the plurality of signal output terminals. According to an embodiment, three data lines can be connected to each of the first and second signal output terminals DS1 and DS2. The first signal output terminal DS1 can supply signals to pixels arranged in first to third columns via the plurality of data lines respectively connected thereto. The second signal output terminal DS2 can supply signals to pixels arranged in third to fifth columns via the plurality of data lines respectively connected thereto.

The pixels arranged in the third column can be alternately connected to the first and second signal output terminals DS1 and DS2. Accordingly, each of the first and second signal output terminals DS1 and DS2 can be connected to pixels arranged in 2.5 columns. According to an embodiment, each of the first and second signal output terminals DS1 and DS2 can be connected to pixels arranged in 2.5 columns on average.

A first-1a data line DL1-1a, a first-2a data line DL1-2a, and a first-3a data line DL1-3a can be connected to the first signal output terminal DS1. A first-1b data line DL1-1b, a first-2b data line DL1-2b, and a first-3b data line DL1-3b can be connected to the second signal output terminal DS2.

The first-1a data line DL1-1a can transfer signals to pixels PXL1a and PXL1b arranged in the first column. The first-2a data line DL1-2a can transfer signals to the pixels PXL2a and PXL2b arranged in the second column.

The first-3a data line DL1-3a can transfer signals to the pixels PXL3a or PXL3b arranged in the third column. The first-1b data line DL1-1b can transfer signals to the pixels PXL3a or PXL3b arranged in the third column. Accordingly, the pixels PXL3a and PXL3b arranged in the third column can alternately be supplied with signals from the first-3a data line DL1-3a and the first-1b data line DL1-1b.

Alternately or successively transferring signals to pixels can mean alternately transferring signals from the first signal output terminal and the second signal output terminal to pixels arranged in the second direction Y, or it can mean transferring signals from the first signal output terminal to some of the sub-pixels included in each pixel, while transferring signals from the second signal output terminal to the remaining sub-pixels. When a signal from a different signal output terminal is transferred to at least one of the sub-pixels included within each pixel, it can be considered as signals being alternately transferred to the pixels.

Further, alternately or successively transferring signals to pixels can mean alternately connecting the first signal output terminal and the second signal output terminal to pixels arranged in the second direction Y. Furthermore, alternately or successively transferring signals to pixels can mean connecting the first signal output terminal to one, two, or more pixels arranged in the second direction Y, and connecting the second signal output terminal to one, two, or more pixels arranged in the second direction Y, such that the first and second signal output terminals are alternately connected to the pixels arranged in the second direction Y as a whole.

The first-2b data line DL1-2b can transfer signals to pixels PXL4a and PXL4b arranged in the fourth column. The first-3b data line DL1-3b can transfer signals to pixels PXL5a and PXL5b arranged in the fifth column.

The first-a pixel PXL1a can be disposed at an intersection of the first-1a data line DL1-1a and the first scan line SL1, and can be supplied with signals therefrom. The first-b pixel PXL1b can be disposed at an intersection of the first-1a data line DL1-1a and the fourth scan line SL4, and can be supplied with signals therefrom.

The second-a pixel PXL2a can be disposed at an intersection of the first-2a data line DL1-2a and the second scan line SL2, and can be supplied with signals therefrom. The second-b pixel PXL2b can be disposed at an intersection of the first-2a data line DL1-2a and the fifth scan line SL5, and can be supplied with signals therefrom.

The third-a pixel PXL3a can be disposed at an intersection of the first-3a data line DL1-3a and the third scan line SL3, and can be supplied with signals therefrom. Alternatively, the third-a pixel PXL3a can be disposed at an intersection of the first-1b data line DL1-1b and the third scan line SL3, and can be supplied with signals therefrom. In addition, among a plurality of sub-pixels included in the third-a pixel PXL3a, some sub-pixels can be supplied with signals from the first-3a data line DL1-3a and the third scan line SL3, while the remaining sub-pixels can be supplied with signals from the first-1b data line DL1-1b and the third scan line SL3.

The third-b pixel PXL3b can be supplied with signals from a data line not connected to the third-a pixel PXL3a among the first-3a data line DL1-3a and the first-1b data line DL1-1b, and from the fifth scan line SL5. For example, when the third-a pixel PXL3a is connected to the first-3a data line DL1-3a, the third-b pixel PXL3b can be connected to the first-1b data line DL1-1b. For example, when the third-a pixel PXL3a is connected to the first-1b data line DL1-1b, the third-b pixel PXL3b can be connected to the first-3a data line DL1-3a.

For example, when some of the sub-pixels of the third-a pixel PXL3a are connected to the first-3a data line DL1-3a and the remaining sub-pixels are connected to the first-1b data line DL1-1b, the third-b pixel PXL3b can be configured such that sub-pixels corresponding to some sub-pixels of the third-a pixel PXL3a are connected to the first-1b data line DL1-1b, and sub-pixels corresponding to the remaining sub-pixels of the third-a pixel PXL3a are connected to the first-3a data line DL1-3a.

The fourth-a pixel PXL4a can be disposed at an intersection of the first-2b data line DL1-2b and the second scan line SL2, and can be supplied with signals therefrom. The fourth-b pixel PXL4b can be disposed at an intersection of the first-2b data line DL1-2b and the third scan line SL3, and can be supplied with signals therefrom.

The fifth-a pixel PXL5a can be disposed at an intersection of the first-3b data line DL1-3b and the first scan line SL1, and can be supplied with signals therefrom. The fifth-b pixel PXL5b can be disposed at an intersection of the first-3b data line DL1-3b and the fourth scan line SL4, and can be supplied with signals therefrom.

The number of first and second signal output terminals DS1 and DS2 can vary depending on the number of sub-pixels SP included in each pixel PXL. Referring to FIG. 4, when each pixel includes three sub-pixels, a first-1 signal output terminal DS1-1, a first-2 signal output terminal DS1-2, and a first-3 signal output terminal DS1-3, which contain information of different colors, can correspond to the first signal output terminal DS1. In this case, a second-1 signal output terminal DS2-1, a second-2 signal output terminal DS2-2, and a second-3 signal output terminal DS2-3, which contain information of different colors, can correspond to the second signal output terminal DS2.

The signal output terminal DS1-1 and the second-1 signal output terminal DS2-1 can contain information of the same color. The first-2 signal output terminal DS1-2 and the second-2 signal output terminal DS2-2 can contain information of the same color. The first-3 signal output terminal DS1-3 and the second-3 signal output terminal DS2-3 can contain information of the same color.

The first-1a to first-3a data lines DL1-1a, DL1-2a, and DL1-3a can be connected to the first-1 signal output terminal DS1-1 and supplied with the same data signal. The second-1a to second-3a data lines DL2-1a, DL2-2a, and DL2-3a can be connected to the first-2 signal output terminal DS1-2 and can be supplied with the same data signal. The third-1a to third-3a data lines DL3-1a, DL3-2a, and DL3-3a can be connected to the first-3 signal output terminal DS1-3 and supplied with the same data signal.

The first-1b to first-3b data lines DL1-1b, DL1-2b, and DL1-3b can be connected to the second-1 signal output terminal DS2-1 and supplied with the same data signal. The second-1b to second-3b data lines DL2-1b, DL2-2b, and DL2-3b can be connected to the second-2 signal output terminal DS2-2 and supplied with the same data signal. The third-1b to third-3b data lines DL3-1b, DL3-2b, and DL3-3b can be connected to the second-3 signal output terminal DS2-3 and supplied with the same data signal.

The first-1a and first-1b sub-pixels SP1-1a and SP1-1b arranged in the first-1 column can be connected to the first-1a data line DL1-1a. The first-2a and first-2b sub-pixels SP1-2a and SP1-2b arranged in the first-2 column can be connected to the second-1a data line DL2-1a. The first-3a and first-3b sub-pixels SP1-3a and SP1-3b arranged in the first-3 column can be connected to the third-1a data line DL3-1a.

The second-1a and second-1b sub-pixels SP2-1a and SP2-1b arranged in the second-1 column can be connected to the first-2a data line DL1-2a. The second-2a and second-2b sub-pixels SP2-2a and SP2-2b arranged in the second-2 column can be connected to the second-2a data line DL2-2a. The second-3a and second-3b sub-pixels SP2-3a and SP2-3b arranged in the second-3 column can be connected to the third-2a data line DL3-2a.

The third-1a and third-1b sub-pixels SP3-1a and SP3-1b arranged in the third-1 column can be connected to the first-3a data line DL1-3a or the first-1b data line DL1-1b, respectively. The third-2a and third-2b sub-pixels SP3-2a and SP3-2b arranged in the third-2 column can be connected to the second-3a data line DL2-3a or the second-1b data line DL2-1b, respectively. The third-3a and third-3b sub-pixels SP3-3a and SP3-3b arranged in the third-3 column can be connected to the third-3a data line DL3-3a or the third-1b data line DL3-1b.

For example, according to an embodiment of the present disclosure, in the pixels arranged in the third column, the first-3a, second-3a, and third-3a data lines DL1-3a, DL2-3a, and DL3-3a corresponding to the first signal output terminal can be connected to the third-1a to third-3a sub-pixels SP3-1a, SP3-2a, and SP3-3a arranged in the first row, respectively, and the first-1b, second-1b, and third-1b data lines DL1-1b, DL2-1b, and DL3-1b corresponding to the second signal output terminal can be connected to the third-1b to third-3b sub-pixels SP3-1b, SP3-2b, and SP3-3b arranged in the second row, respectively. However, the embodiment according to the present disclosure is not limited thereto, and sub-pixels arranged in each column can alternately be supplied with signals from data lines connected to different signal output terminals.

The fourth-1a and fourth-1b sub-pixels SP4-1a and SP4-1b arranged in the fourth-1 column can be connected to the first-2b data line DL1-2b. The fourth-2a and fourth-2b sub-pixels SP4-2a and SP4-2b arranged in the fourth-2 column can be connected to the second-2b data line DL2-2b. The fourth-3a and fourth-3b sub-pixels SP4-3a and SP4-3b arranged in the fourth-3 column can be connected to the third-2b data line DL3-2b.

The fifth-1a and fifth-1b sub-pixels SP5-1a and SP5-1b arranged in the fifth-1 column can be connected to the first-3b data line DL1-3b. The fifth-2a and fifth-2b sub-pixels SP5-2a and SP5-2b arranged in the fifth-2 column can be connected to the second-3b data line DL2-3b. The fifth-3a and fifth-3b sub-pixels SP5-3a and SP5-3b arranged in the fifth-3 column can be connected to the third-3b data line DL3-3b.

Referring to FIG. 5, when each pixel includes four sub-pixels, the first signal output terminal DS1 can include the first-1 signal output terminal DS1-1, the first-2 signal output terminal DS1-2, the first-3 signal output terminal DS1-3, and the first-4 signal output terminal DS1-4, which contain information of different colors. In this case, the second signal output terminal DS2 can include the second-1 signal output terminal DS2-1, the second-2 signal output terminal DS2-2, the second-3 signal output terminal DS2-3, and a second-4 signal output terminal DS2-4, which contain information of different colors.

The first-1 signal output terminal DS1-1 and the second-1 signal output terminal DS2-1 can contain information of the same color. The first-2 signal output terminal DS1-2 and the second-2 signal output terminal DS2-2 can contain information of the same color. The first-3 signal output terminal DS1-3 and the second-3 signal output terminal DS2-3 can contain information of the same color. The first-4 signal output terminal DS1-4 and the second-4 signal output terminal DS2-4 can contain information of the same color.

Therefore, with respect to sub-pixels arranged in the third column, which is an area A, the data lines containing information of the same color can be alternately connected to sub-pixels arranged in the same column. For example, a plurality of data lines are concentrated in area A, and sub-pixels arranged in the same column can be arranged to have the same color.

The first-1a to first-3a data lines DL1-1a, DL1-2a, and DL1-3a can be connected to the first-1 signal output terminal DS1-1. The second-1a to second-3a data lines DL2-1a, DL2-2a, and DL2-3a can be connected to the first-2 signal output terminal DS1-2. The third-1a to third-3a data lines DL3-1a, DL3-2a, and DL3-3a can be connected to the first-3 signal output terminal DS1-3. The fourth-1a to fourth-3a data lines DL4-1a, DL4-2a, and DL4-3a can be connected to the first-4 signal output terminal DS1-4.

The first-1b to first-3b data lines DL1-1b, DL1-2b, and DL1-3b can be connected to the second-1 signal output terminal DS2-1. The second-1b to second-3b data lines DL2-1b, DL2-2b, and DL2-3b can be connected to the second-2 signal output terminal DS2-2. The third-1b to third-3b data lines DL3-1b, DL3-2b, and DL3-3b can be connected to the second-3 signal output terminal DS2-3. The fourth-1b to fourth-3b data lines DL4-1b, DL4-2b, and DL4-3b can be connected to the second-4 signal output terminal DS2-4.

Compared to the embodiment including three sub-pixels, the embodiment including four sub-pixels can include one more data line for each signal output terminal. In addition to the connection relationship between sub-pixels and data lines implemented in the three sub-pixels, a connection between sub-pixels and data lines can be further included in each pixel. Therefore, a description of the same structure as the connection relationship between sub-pixels and data lines implemented in the aforementioned three sub-pixels will be omitted.

The embodiment for four sub-pixels can further include the first-4, second-4, third-4, fourth-4, and fifth-4 columns compared to the three sub-pixels. The first-4a and first-4b sub-pixels SP1-4a and SP1-4b arranged in the first-4 column can be connected to the fourth-1a data line DL4-1a. The second-4a and second-4b sub-pixels SP2-4a and SP2-4b arranged in the second-4 column can be connected to the fourth-2a data line DL4-2a. The fourth-4a and fourth-4b sub-pixels SP4-4a and SP4-4b arranged in the fourth-4 column can be connected to the fourth-2b data line DL4-2b. The fifth-4a and fifth-4b sub-pixels SP5-4a and SP5-4b arranged in the fifth-4 column can be connected to the fourth-3b data line DL4-3b.

The sub-pixels arranged in the third column can alternately be supplied with signals from data lines corresponding to the first signal output terminal and data lines corresponding to the second signal output terminal. In an embodiment including four sub-pixels, the connection relationship between sub-pixels arranged in the third column and data lines will be described with reference to FIGS. 6A to 6D. However, the present disclosure is not limited thereto, and sub-pixels arranged in each column can selectively and alternately be supplied with signals from different signal output terminals.

Each of the four sub-pixels arranged in each row can be selectively driven by a data line corresponding to the first signal output terminal or the second signal output terminal. Since the area A is an area where data lines of different signals are concentrated, signal interference between different data lines can occur. The signal interference can cause a problem of luminance degradation of pixels. To prevent this, in the present disclosure, four sub-pixels included in one pixel can be connected to data lines corresponding to the first signal output terminal or the second signal output terminal in units of two sub-pixels.

Referring to FIGS. 6A to 6D, four sub-pixels can be driven by being connected to each of the first signal output terminal and the second signal output terminal in units of two sub-pixels. For example, the sub-pixels can be connected to the first or second signal output terminal in units of third-1a and third-2a sub-pixels SP3-1a and SP3-2a, third-3a and third-4a sub-pixels SP3-3a and SP3-4a, third-1b and third-2b sub-pixels SP3-1b and SP3-2b, and third-3b and third-4b sub-pixels SP3-3b and SP3-4b.

For example, the sub-pixels SP3-1a and SP3-1b arranged in the third-1 column and the sub-pixels SP3-2a and SP3-2b arranged in the third-2 column can each include one of white and blue. For example, the sub-pixels SP3-3a and SP3-3b arranged in the third-3 column and the sub-pixels SP3-4a and SP3-4b arranged in the third-4 column can each include one of red and green, but the present disclosure is not limited thereto.

The first-signal-output-terminal-driving-area C1 can be the area driven by the first-3a, second-3a, third-3a, and fourth-3a data lines DL1-3a, DL2-3a, DL3-3a, and DL4-3a corresponding to the first signal output terminal, and the second-signal-output-terminal-driving-area C2 can be the area driven by the first-1b, second-1b, third-1b, and fourth-1b data lines DL1-1b, DL2-1b, DL3-1b, and DL4-1b corresponding to the second signal output terminal.

Referring to FIG. 6A, the third-1a, the third-2a, third-3b, and third-4b sub-pixels SP3-1a, SP3-2a, SP3-3b, and SP3-4b can belong to the first-signal-output-terminal-driving-area C1. The third-3a, third-4a, third-1b, and third-2b sub-pixels SP3-3a, SP3-4a, SP3-1b, and SP3-2b can belong to the second-signal-output-terminal-driving-area C2. Accordingly, the sub-pixels arranged in the third column can be alternately connected to different signal output terminals.

Referring to FIG. 6B, the third-1a to third-4a sub-pixels SP3-1a, SP3-2a, SP3-3a, and SP3-4a can belong to the first-signal-output-terminal-driving-area C1. The third-1b to third-4b sub-pixels SP3-1b, SP3-2b, SP3-3b, and SP3-4b can belong to the second-signal-output-terminal-driving-area C2. Accordingly, the sub-pixels arranged in the third column can be alternately connected to different signal output terminals.

Referring to FIG. 6C, the third-1a to third-4a sub-pixels SP3-1a, SP3-2a, SP3-3a, and SP3-4a can belong to the second-signal-output-terminal-driving-area C2. The third-1b to third-4b sub-pixels SP3-1b, SP3-2b, SP3-3b, and SP3-4b can belong to the first-signal-output-terminal-driving-area C1. Accordingly, the sub-pixels arranged in the third column can be alternately connected to different signal output terminals.

Referring to FIG. 6D, the third-1a, third-2a, third-3b, and third-4b sub-pixels SP3-1a, SP3-2a, SP3-3b, and SP3-4b can belong to the second-signal-output-terminal-driving-area C2. The third-3a, third-4a, third-1b, and third-2b sub-pixels SP3-3a, SP3-4a, SP3-1b, and SP3-2b can belong to the first-signal-output-terminal-driving-area C1. Accordingly, the sub-pixels arranged in the third column can be alternately connected to different signal output terminals.

Referring to FIGS. 4 and 5, a reference voltage Vref can be supplied to the reference voltage line VL2 from a pad part. The reference voltage line VL2 can be disposed in the same direction as the data lines. The reference voltage line VL2 can be disposed between the plurality of pixels PXL repeatedly arranged in a row direction. The reference voltage line VL2 can supply a voltage to sub-pixels adjacent to the left and right thereof. For example, the reference voltage line VL2 can be connected to a second transistor T2 in the circuit part CA of each sub-pixel.

A driving voltage line VL1-1 can be supplied with a pixel driving voltage EVDD from the pad part. According to an embodiment of the present disclosure, the pixel driving voltage EVDD can be supplied via a first driving voltage pattern VL1-2 and a second driving voltage pattern VL1-3 formed in a direction intersecting the driving voltage line VL1-1. The driving voltage line VL1-1 and the first driving voltage pattern VL1-2, or the driving voltage line VL1-1 and the second driving voltage pattern VL1-3, can be formed on different layers with an insulating layer interposed therebetween, and can be connected to each other via a contact hole, but the present disclosure is not limited thereto.

The driving voltage line VL1-1 can be disposed in the same direction as the data lines. According to an embodiment of the present disclosure, the driving voltage line VL1-1 can be disposed to correspond to the remaining pixels excluding pixels arranged in any one column among five units of pixels repeatedly arranged in a row direction. The driving voltage line VL1-1 according to an embodiment may not be disposed in pixels arranged in the third column, which is the area A in which data lines corresponding to the first signal output terminal and data lines corresponding to the second signal output terminal are concentrated.

For example, in an embodiment including three sub-pixels, the driving voltage line VL1-1 can be disposed between sub-pixels arranged in the first and second columns of each pixel, while excluding the area A. For example, in an embodiment including four sub-pixels, the driving voltage line VL1-1 can be disposed between sub-pixels arranged in the second and third columns of each pixel, while excluding the area A.

The first driving voltage pattern VL1-2 can be disposed in the first direction X. According to an embodiment, the first driving voltage pattern VL1-2 can be disposed between the circuit parts CA facing each other in the second direction Y. For example, the first driving voltage pattern VL1-2 can be disposed at the upper end (upper end in the Y-axis direction) of pixels arranged in the first row and at the lower end (lower end in the Y-axis direction) of pixels arranged in the second row. For example, the first driving voltage pattern VL1-2 may not be disposed in the area where the third scan line SL3 is disposed, which is between the pixels arranged in the first row and the pixels arranged in the second row.

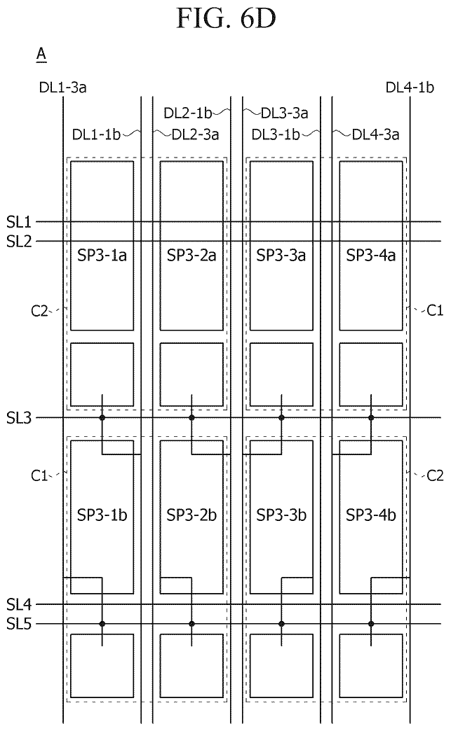

The first driving voltage pattern VL1-2 can be connected to the circuit part CA of each adjacent sub-pixel. A sub-pixel in which the circuit part CA is arranged closer to the first driving voltage pattern VL1-2 than the light-emitting part EA and a sub-pixel in which the light-emitting part EA is arranged closer to the first driving voltage pattern VL1-2 than the circuit part CA, can have different structures for connection to the first driving voltage pattern VL1-2. This will be described with reference to FIGS. 7 and 8.

FIG. 7 is a plan view illustrating a portion of the area A of FIG. 5 according to a first embodiment. FIG. 8 is a plan view illustrating the area B of FIG. 5.

Referring to FIGS. 7 and 8, sub-pixels according to an embodiment can include a first electrode 161 including a light-emitting part EA and a circuit part CA, and a plurality of transistors T1, T2, and T3 and a light-shielding pattern 111 disposed in the circuit part CA. For example, the first driving voltage pattern VL1-2 can be connected to the third transistor T3 of each adjacent sub-pixel, but the present disclosure is not limited thereto.

Referring to FIG. 7, since the driving voltage line VL1-1 is not disposed in the area A of FIG. 5 in which the data lines corresponding to the first and second signal output terminals are concentrated, a sub-pixel in the area A of FIG. 5, in which the light-emitting part EA is disposed closer to the first driving voltage pattern VL1-2 than the circuit part CA, can be connected to the first driving voltage pattern VL1-2 via an extension pattern T3-1 of the third transistor T3.

The extension pattern T3-1 can be formed by extending either a source electrode or a drain electrode of the third transistor T3. However, the present disclosure is not limited thereto. For example, the extension pattern T3-1 can be formed on a layer different from that of the source and drain electrodes of the third transistor T3 and connected to the third transistor T3 via a contact hole.

The extension pattern T3-1 can be connected to the first driving voltage pattern VL1-2 from the circuit part CA through the light-emitting part EA. The extension pattern T3-1 can be disposed to minimize interference with the light-emitting part EA. The extension pattern T3-1 can be disposed to overlap the first and second portions 161a and 161b of the first electrode 161, but not to overlap the third portion 161c of the first electrode 161, so as to minimize overlap with the light-emitting part EA.

Referring to FIG. 8, in areas other than the area A of FIG. 5, the driving voltage line VL1-1 is disposed for each pixel, and accordingly, a sub-pixel in which the light-emitting part EA is disposed closer to the first driving voltage pattern VL1-2 than the circuit part CA can be connected to the second driving voltage pattern VL1-3, which is disposed to intersect the driving voltage line VL1-1. In other words, in areas other than the area A of FIG. 5, the sub-pixels of the pixel connected to the third scan line SL3 can be connected to the second driving voltage pattern VL1-3. The second driving voltage pattern VL1-3 can be connected to the driving voltage line VL1-1 to supply a driving voltage to the corresponding pixel.

The second driving voltage pattern VL1-3 can be formed across the circuit parts of the plurality of sub-pixels. The second driving voltage pattern VL1-3 can extend from a point intersecting the driving voltage line VL1-1 to both sides in the first direction X to be electrically connected to a source or drain electrode of the third transistor T3 of adjacent sub-pixels.

Referring to FIGS. 7 and 8, the first electrode 161 can have a minimum width in some areas to minimize interference between the first electrode 161 and the scan lines SL1, SL2, SL4, and SL5.

The first electrode 161 can include a first portion 161a, a second portion 161b, and a third portion 161c. The first portion 161a and the second portion 161b can be disposed to be adjacent to each other with the third portion 161c interposed therebetween. The third portion 161c is disposed between the first and second portions 161a and 161b, and can overlap the first and second scan lines SL1 and SL2 or the fourth and fifth scan lines SL4 and SL5.

The third portion 161c overlapping the scan lines SL1, SL2, SL4, and SL5 can have a first-1 width W1-1 narrower than a first-2 width W1-2 of the first portion 161a or the second portion 161b to minimize signal interference. The first portion 161a and the second portion 161b can have substantially the same first-2 width W1-2. The minimum width of the first-1 width W1-1 of the third portion 161c can be determined according to the etching characteristics of the first electrode 161. The first-1 width W1-1 can be formed to be narrower than the first-2 width W1-2 by a factor ¼ to ½ times, but the present disclosure is not limited thereto.

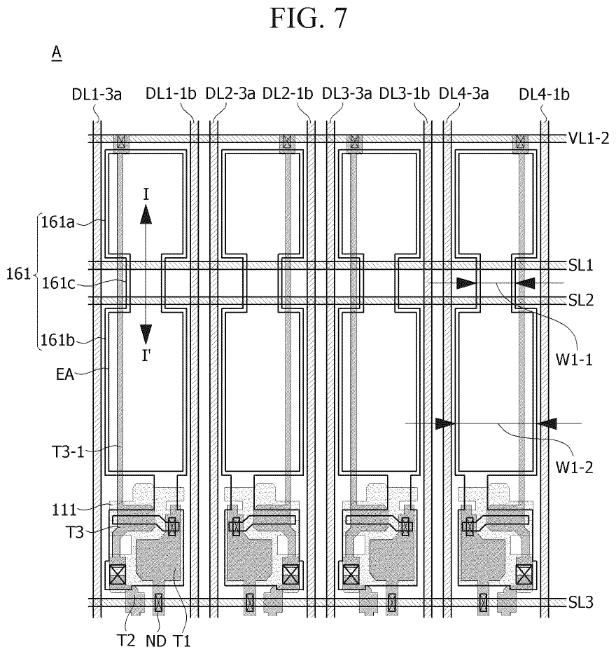

FIG. 9 is a cross-sectional view taken along line I-I′ of FIG. 7.

Referring to FIG. 9, according to an embodiment of the present disclosure, the display panel can include a substrate 10, a first insulating layer 20, a second insulating layer 30, a third insulating layer 40, a fourth insulating layer 50, and a light-emitting element 160 including a first electrode 161, an intermediate layer 163, and a second electrode 165 disposed on the fourth insulating layer 50. The first and second scan lines SL1 and SL2 can be formed on the second insulating layer 30 and disposed between the second and third insulating layers 30 and 40.

The first insulating layer 20 can cover the substrate 10. The first insulating layer 20 can be referred to as a buffer layer. For example, the first insulating layer 20 can be made of a type of inorganic insulating film, and can be formed as a single layer or multiple layers.

The second insulating layer 30 can be disposed on the first insulating layer 20. The second insulating layer 30 can be referred to as an interlayer insulating film. For example, the second insulating layer 30 can be made of a type of inorganic insulating film, and can be formed as a single layer or multiple layers.

The third insulating layer 40 can be disposed on the second insulating layer 30. The third insulating layer 40 can be referred to as a passivation layer. For example, the third insulating layer 40 can be made of a type of inorganic insulating film, and can be formed as a single layer or multiple layers.

The fourth insulating layer 50 can be disposed on the third insulating layer 40 to planarize a surface step of the third insulating layer 40. The fourth insulating layer 50 can be referred to as a planarization film or an overcoat layer. For example, the fourth insulating layer 50 can be made of a type of organic insulating film, and can be formed as a single layer or multiple layers.

The first electrode 161 can be disposed in each of the sub-pixels. The first electrode 161 can include the light-emitting part EA and the circuit part CA. In a case where the display panel of the present disclosure is a top emission type, the first electrode 161 can be formed to have higher reflection efficiency than the second electrode 165. However, the present disclosure is not limited thereto, and in the case of a bottom emission type, the second electrode 165 can be formed to have higher reflection efficiency than the first electrode 161.

For example, the first electrode 161 can be formed in a multi-layer structure including a transparent conductive film and an opaque conductive film with high reflection efficiency.

The intermediate layer 163 is disposed on the first electrode 161 and can be formed throughout the substrate 10. The intermediate layer 163 can refer to a single or multiple stack organic layer composed of multiple layers including a hole injection layer (HIL), a hole transport layer (HTL), an emission layer (EML), an electron transport layer (ETL), and an electron injection layer (EIL).

The second electrode 165 is disposed on the intermediate layer 163 to face the first electrode 161. The second electrode 165 can be formed throughout the substrate 10.

When the display panel of the present disclosure is a top emission type, the second electrode 165 can be made of a transparent conductive layer.

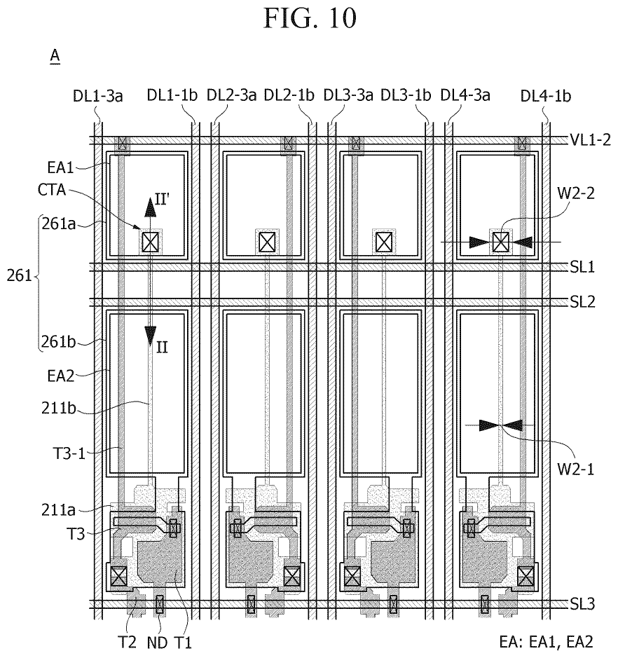

FIG. 10 is a plan view illustrating a portion of the area A of FIG. 5 according to a second embodiment. FIG. 11 is a cross-sectional view taken along line II-II′ of FIG. 10. FIGS. 10 and 11 show an embodiment capable of preventing interference between a first electrode and scan lines. In FIGS. 10 and 11, descriptions of the same configurations as those of the previous embodiment will be omitted or may be briefly provided.

Referring to FIGS. 10 and 11, a first electrode 261 can include a first portion 261a and a second portion 261b. The first electrode 261 according to the second embodiment may not overlap scan lines SL1 and SL2.

According to the embodiment, the first and second portions 261a and 261b can be disposed to be spaced apart from each other. For example, the first and second portions 261a and 261b according to the second embodiment can be in a directly separated state. The second portion 261b of the first electrode 261 can be integrally formed with the first electrode 261 on the circuit part CA and driven by the circuit part CA of the corresponding sub-pixel. The first portion 261a of the first electrode 261, which is spaced apart from the second portion 261b, can be electrically connected to a light-shielding pattern 211a formed in the circuit part CA.

The light-emitting parts EA, EA1, and EA2 are defined on the first electrode 261, so that the light-emitting part EA according to the second embodiment may not overlap an area where the scan lines SL1 and SL2 are disposed. The light-emitting part EA according to the second embodiment can be divided into first and second light-emitting parts EA1 and EA2. The first portion 261a of the first electrode 261 can include the first light-emitting part EA1. The second portion 261b of the first electrode 261 can include the second light-emitting part EA2.

The light-shielding pattern 211 according to the second embodiment can include a light-shielding area 211a, a connection pattern 211b, and a contact pattern 211c. The light-shielding area 211a, the connection pattern 211b, and the contact pattern 211c of the light-shielding pattern 211 can be integrally formed, but the present disclosure is not limited thereto.

The light-shielding area 211a of the light-shielding pattern 211 can be disposed in the circuit part CA.

The connection pattern 211b of the light-shielding pattern 211 can extend from the circuit part CA to the first portion 261a of the first electrode 261. The connection pattern 211b of the light-shielding pattern 211 can be disposed in the second direction Y.

The connection pattern 211b can be formed with a minimum width to minimize signal interference with the scan lines SL1 and SL2. A second-1 width W2-1, which is the minimum width of the connection pattern 211b, can be narrower than the width of the first electrode 261. The minimum width of the second-1 width W2-1 can be determined according to the etching characteristics of the light-shielding pattern 211. The second-1 width W2-1 can be formed to be 1/10 or less of the width of the first electrode 261 in the first direction X, but the present disclosure is not limited thereto.

In addition, since the material of the connection pattern 211b has better etching characteristics than the material of the first electrode 261, the second-1 width W2-1 can be formed to be narrower than the first-1 width W1-1 of the first electrode 261 according to the first embodiment.

The contact pattern 211c electrically connected to the first portion 261a of the first electrode 261 can be disposed on an end of the connection pattern 211b. A second-2 width W2-2 of the contact pattern 211c in the first direction X can be at least wider than the second-1 width W2-1 for good contact.

The first portion 261a of the first electrode 261 and the contact pattern 211c of the light-shielding pattern 211 can be electrically connected at a first contact part CTA. Referring to FIG. 11, the contact pattern 211c of the light-shielding pattern 211 and the first portion 261a of the first electrode 261 can be electrically connected via a contact hole in the first contact part CTA. The first portion 261a of the first electrode 261 can include a first electrode contact part 261a-1 disposed inside the contact hole of the first contact part CTA.

A connection electrode 21 can be further formed to lower electrical resistance between the first portion 261a of the first electrode 261 and the contact pattern 211c of the light-shielding pattern 211. The connection electrode 21 can be disposed on the same layer as the scan lines SL1 and SL2. However, the embodiment according to the present disclosure is not limited thereto, and the first electrode 261 and the contact pattern 211c can be directly contacted without the connection electrode 21.

The first to fourth insulating layers 20, 30, 40, and 50 according to the second embodiment can include a contact hole for contacting the first portion 261a of the first electrode 261 with the contact pattern 211c of the light-shielding pattern 211.

A bank 70 can be disposed between the first portion 261a and the second portion 261b of the first electrode 261. The bank 70 disposed between the first portion 261a and the second portion 261b can overlap the scan lines SL1 and SL2.

The first and second portions 261a and 261b of the first electrode 261, which are spaced apart from each other, are not limited to the embodiments disclosed, and can be driven by forming an electrode pattern on a different layer from the first electrode 261, thereby electrically connecting them to each other.

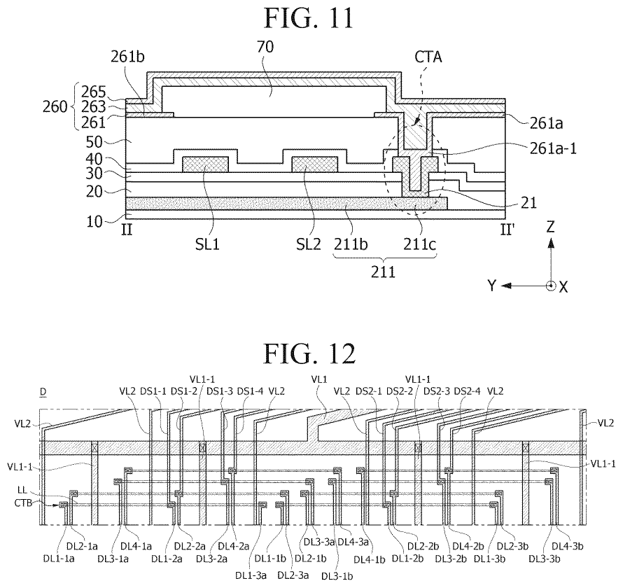

FIG. 12 is a plan view illustrating an area D of FIG. 5. Descriptions of the same reference numerals will be omitted or may be provided briefly.

Referring to FIG. 12, a plurality of data lines DL1-1a to DL1-3a, DL2-1a to DL2-3a, DL3-1a to DL3-3a, DL4-1a to DL4-3a, DL1-1b to DL1-3b, DL2-1b to DL2-3b, DL3-1b to DL3-3b, and DL4-1b to DL4-3b can be connected to the corresponding signal output terminals DS1-1 to DS1-4 and DS2-1 to DS2-4 via a link pattern LL. The link pattern LL disposed in a first direction X can be disposed on a different layer from signal output terminals and data lines disposed in the second direction Y. The link pattern LL can be connected to each of the data lines and signal output terminals disposed on different layers through a second contact part CTB to electrically connect the data lines and the signal output terminals.

For example, the link pattern LL can be disposed on the same layer as the scan lines, and the data lines and signal output terminals can be disposed on the same layer as the light-shielding pattern.

The plurality of driving voltage lines VL1-1 can be connected to a driving voltage output part VL1. The driving voltage output part VL1 can extend from a pad part and be formed in a bar form at an end where the plurality of driving voltage lines VL1-1 meet. The plurality of driving voltage lines VL1-1 are connected to the bar-shaped end of the driving voltage output part VL1, enabling the pixel driving voltage EVDD to be uniformly supplied. The plurality of driving voltage lines VL1-1 and the driving voltage output part VL1 can be electrically connected through a contact part. According to an embodiment, the shape of the driving voltage output part VL1 described herein is merely an example and is not limited thereto.

One or more embodiments of the present disclosure can provide a display panel. The display panel includes a plurality of pixels arranged in a first direction and a second direction that intersect each other, a plurality of signal output terminals configured to supply data signals, and a plurality of data lines connected to the plurality of signal output terminals and configured to transfer the data signals to the pixels, wherein the plurality of pixels includes a first pixel connected to a first signal output terminal, a second pixel connected to a second signal output terminal, and third pixels arranged between the first pixel and the second pixel in the first direction and configured to be alternately connected to the first and second signal output terminals in the second direction.

According to an embodiment of the display panel of the present disclosure, each of the third pixels includes a plurality of sub-pixels, and at least one sub-pixel included in any one of the third pixels is connected to the first signal output terminal, and the remaining sub-pixels are connected to the second signal output terminal.

According to an embodiment of the display panel of the present disclosure, each of the third pixels includes first to fourth sub-pixels, and the first and second sub-pixels included in any one of the third pixels are connected to any one of the first and second signal output terminals, and the third and fourth sub-pixels are connected to the other one of the first and second signal output terminals.

According to an embodiment of the display panel of the present disclosure, the plurality of data lines include: first-1 to first-3 data lines connected to the first signal output terminal; and second-1 to second-3 data lines connected to the second signal output terminal, the first pixel is connected to the first-2 data line, the second pixel is connected to the second-2 data line, the third pixels are alternately connected to the first-3 data line and the second-1 data line in the second direction, and the plurality of pixels further include: a fourth pixel connected to the first-1 data line; and a fifth pixel connected to the second-3 data line.

According to an embodiment of the display panel of the present disclosure, each of the plurality of pixels includes a light-emitting part and a circuit part disposed side by side in one direction, and any one pixel among the first to third pixels has the light-emitting part and the circuit part disposed in a direction opposite to those of the remaining pixels.

According to an embodiment of the display panel of the present disclosure, the display panel comprises first to third scan lines configured to supply scan signals to the plurality of pixels, and the any one pixel, in which the light-emitting part and the circuit part are disposed in the direction opposite to those of the remaining pixels, is connected to the third scan line, and pixels arranged in a first row and pixels arranged in a second row are arranged to be flipped with respect to the third scan line, excluding the pixels connected to the third scan line.

According to an embodiment of the display panel of the present disclosure, the display panel comprises a first electrode disposed in each of the plurality of pixels and including a light-emitting part, and the first and second scan lines overlap the light-emitting part of the first electrode of the pixel connected to the third scan line, the first electrode of the pixel connected to the third scan line includes: a first portion overlapping the first and second scan lines, and second and third portions adjacent to each other with the first portion interposed therebetween, and a first width of the first portion in the first direction is narrower than a second width of the second or third portion in the first direction.

According to an embodiment of the display panel of the present disclosure, the display panel comprises a first electrode disposed in each of the plurality of pixels, and a light-shielding pattern disposed in the circuit part of each of the plurality of pixels, and the first electrode of the pixel connected to the third scan line includes: a first portion; and a second portion spaced apart from the first portion and having an overlapping area with the light-shielding pattern, and the first and second scan lines are disposed in a spaced area between the first portion and the second portion of the first electrode of the pixel connected to the third scan line, the first portion of the first electrode is electrically connected to a connection pattern extending from the light-shielding pattern to the first portion, and a first width of the connection pattern in the first direction is narrower than a second width of the first or second portion of the first electrode in the first direction.

According to an embodiment of the display panel of the present disclosure, the display panel comprises a driving voltage line configured to supply a pixel driving voltage; and a first driving voltage pattern electrically connected to the driving voltage line and disposed in a direction intersecting the driving voltage line, and the third pixel includes an extension pattern in which a source electrode or a drain electrode of a transistor disposed in a circuit part is extended, the driving voltage line is disposed in each of the first and second pixels, but not in the third pixel, the first driving voltage pattern is disposed on one side of a light-emitting part of the third pixel, and the extension pattern is electrically connected to the first driving voltage pattern.

According to an embodiment of the display panel of the present disclosure, the display panel comprises a driving voltage line configured to supply a pixel driving voltage; and a second driving voltage pattern electrically connected to the driving voltage line and disposed in a direction intersecting the driving voltage line, and wherein each of the plurality of pixels includes a plurality of sub-pixels, the second driving voltage pattern is formed across the plurality of sub-pixels of the first pixel, a source electrode or a drain electrode of a transistor disposed in a circuit part of each of the plurality of sub-pixels of the first pixel is electrically connected to the second driving voltage pattern.

Although embodiments of the present invention have been described in more detail with reference to the accompanying drawings, the present invention is not necessarily limited to these embodiments, and can be variously modified and implemented within a scope not departing from the technical spirit of the present invention.

Therefore, the embodiments disclosed in the present invention are not intended to limit the technical spirit of the present invention but to indicate the technical spirit, and the scope of the technical spirit of the present invention is not limited by these embodiments.

Therefore, the embodiments described above should be understood in all respects as illustrative and not restrictive.

The scope of protection of the present invention should be interpreted by the claims, and all technical spirits within an equivalent scope thereto should be interpreted as being included in the scope of the present invention.

### LIST OF REFERENCE NUMBERS

DS1: First signal output terminal
DS2: Second signal output terminal
DL1-1a, DL1-2a, DL1-3a: First-1a to first-3a data lines
DL1-1b, DL1-2b, DL1-3b: First-1b to first-3b data lines
SL1, SL2, SL3, SL4, SL5: First to fifth scan lines
T3-1: Extension pattern
VL1-1: Driving voltage line
VL1-2, VL1-3: First driving voltage pattern, Second driving voltage pattern
LL: Link pattern
211B: Connection pattern

What is claimed is:

1. A display panel comprising:
a plurality of pixels arranged in a first direction and a second direction that intersect each other;
a plurality of signal output terminals configured to supply data signals; and
a plurality of data lines connected to the plurality of signal output terminals and configured to transfer the data signals to the plurality of pixels,
wherein the plurality of pixels include:
a first pixel connected to a first signal output terminal among the plurality of signal output terminals;
a second pixel connected to a second signal output terminal among the plurality of signal output terminals; and
third pixels arranged between the first pixel and the second pixel in the first direction and configured to be alternately connected to the first signal output terminal and the second signal output terminal in the second direction.

2. The display panel of claim 1, wherein each of the third pixels includes a plurality of sub-pixels, and
wherein at least one sub-pixel included in any one of the third pixels is connected to the first signal output terminal, and remaining sub-pixels are connected to the second signal output terminal.

3. The display panel of claim 1, wherein each of the third pixels includes a first sub-pixel, a second sub-pixel, a third sub-pixel, and a fourth sub-pixel, and
wherein the first and second sub-pixels included in any one of the third pixels are connected to any one of the first and second signal output terminals, and the third and fourth sub-pixels are connected to the other one of the first and second signal output terminals.

4. The display panel of claim 1, wherein the plurality of data lines include:
a first-1 data line, a first-2 data line and a first-3 data line connected to the first signal output terminal; and
a second-1 data line, a second-2 data line and a second-3 data line connected to the second signal output terminal,
wherein the first pixel is connected to the first-2 data line, and
wherein the second pixel is connected to the second-2 data line.

5. The display panel of claim 4, wherein the third pixels are alternately connected to the first-3 data line and the second-1 data line in the second direction.

6. The display panel of claim 5, wherein the plurality of pixels further include:
a fourth pixel connected to the first-1 data line; and
a fifth pixel connected to the second-3 data line.

7. The display panel of claim 1, wherein each of the plurality of pixels includes a light-emitting part and a circuit part disposed side by side in one direction, and
wherein any one pixel among the first to third pixels has the light-emitting part and the circuit part disposed in a direction opposite to those of the remaining pixels among the first to third pixels.

8. The display panel of claim 7, further comprising:
a first scan line, a second scan line and a third scan line configured to supply scan signals to the plurality of pixels,
wherein the any one pixel, in which the light-emitting part and the circuit part are disposed in the direction opposite to those of the remaining pixels, is connected to the third scan line in the first row and the second row.

9. The display panel of claim 8, wherein pixels arranged in a first row and pixels arranged in a second row are arranged to be flipped with respect to the third scan line, excluding the pixels connected to the third scan line.

10. The display panel of claim 8, further comprising:
a first electrode disposed in each of the plurality of pixels and including a light-emitting part,
wherein the first and second scan lines overlap the light-emitting part of the first electrode of the pixel connected to the third scan line.

11. The display panel of claim 10, wherein the first electrode of the pixel connected to the third scan line includes:
a first portion overlapping the first and second scan lines; and
second and third portions adjacent to each other with the first portion interposed therebetween.

12. The display panel of claim 11, wherein a first width of the first portion in the first direction is narrower than a second width of the second or third portion in the first direction.

13. The display panel of claim 8, further comprising:
a first electrode disposed in each of the plurality of pixels; and
a light-shielding pattern disposed in the circuit part of each of the plurality of pixels.

14. The display panel of claim 13, wherein the first electrode of the pixel connected to the third scan line includes:
a first portion; and
a second portion spaced apart from the first portion and having an overlapping area with the light-shielding pattern, and
wherein the first and second scan lines are disposed in a spaced area between the first portion and the second portion of the first electrode of the pixel connected to the third scan line.

15. The display panel of claim 14, wherein the first portion of the first electrode is electrically connected to a connection pattern extending from the light-shielding pattern to the first portion, and
wherein a first width of the connection pattern in the first direction is narrower than a second width of the first or second portion of the first electrode in the first direction.

16. The display panel of claim 1, further comprising:
a driving voltage line configured to supply a pixel driving voltage, and
wherein the driving voltage line is disposed in each of the first and second pixels.

17. The display panel of claim 16, further comprising:
a first driving voltage pattern electrically connected to the driving voltage line and disposed in a direction intersecting the driving voltage line, and
wherein one of the third pixels includes an extension pattern in which a source electrode or a drain electrode of a transistor disposed in a circuit part is extended, and
wherein the extension pattern is electrically connected to the first driving voltage pattern.

18. The display panel of claim 17, wherein the first driving voltage pattern is disposed on one side of a light-emitting part of the third pixel including the extension pattern.

19. The display panel of claim 1, further comprising:
a driving voltage line configured to supply a pixel driving voltage; and
a second driving voltage pattern electrically connected to the driving voltage line and disposed in a direction intersecting the driving voltage line,
wherein each of the plurality of pixels includes a plurality of sub-pixels, and
wherein the second driving voltage pattern is extending across the plurality of sub-pixels of the first pixel.

20. The display panel of claim 19, wherein a source electrode or a drain electrode of a transistor disposed in a circuit part of each of the plurality of sub-pixels of the first pixel is electrically connected to the second driving voltage pattern.
